(19) United States
(12) Patent Application Publication
(10) Pub. No.: US 2025/0218725 A1
(43) Pub. Date: Jul. 3, 2025

(54) PLASMA PROCESSING APPARATUS AND PLASMA PROCESSING METHOD

(71) Applicant: Tokyo Electron Limited, Tokyo (JP)

(72) Inventor: Hiroshi TSUJIMOTO, Miyagi (JP)

(73) Assignee: Tokyo Electron Limited, Tokyo (JP)

(21) Appl. No.: 19/084,788

(22) Filed: Mar. 20, 2025

Related U.S. Application Data
(63) Continuation of application No. PCT/JP2023/029469, filed on Aug. 14, 2023.

(30) Foreign Application Priority Data
Sep. 21, 2022 (JP) 2022-150094

(51) Int. Cl. H01J 37/32

(52) U.S. Cl. CPC H01J 37/32174; H01J 37/32091

(57) ABSTRACT

A plasma processing apparatus is disclosed, including a chamber, a substrate support, a plasma generator, and a bias power supply. The substrate support is provided in the chamber. The plasma generator is configured to generate plasma from gas in the chamber. The bias power supply is configured to apply a sequence of a plurality of voltage pulses as an electrical bias to the substrate support. The bias power supply is configured to adjust a maximum voltage level of each of the voltage pulses by adjusting a length of an ON period of each of the voltage pulses.

### CROSS-REFERENCE TO RELATED APPLICATIONS

This application is a bypass continuation application of international application No. PCT/JP2023/029469 having an international filing date of Aug. 14, 2023 and designating the United States, the international application being based upon and claiming the benefit of priority from Japanese Patent Application No. 2022-150094, filed on Sep. 21, 2022, the entire contents of each are incorporated herein by reference.

### TECHNICAL FIELD

An exemplary embodiment of the present disclosure relates to a plasma processing apparatus and a plasma processing method.

### BACKGROUND

A plasma processing apparatus has been used in plasma processing for a substrate. The plasma processing apparatus includes a chamber and a substrate support. The substrate support is provided in the chamber. The plasma processing apparatus disclosed in Patent Document 1 below applies a DC negative pulse voltage to the substrate support in order to draw ions to the substrate from plasma generated in the chamber.

### PRIOR ART DOCUMENT

### Patent Document

Patent Document 1: Japanese patent laid-open publication No. 2009-187975

### SUMMARY

According to one exemplary embodiment, there is provided a plasma processing apparatus. The plasma processing apparatus includes a chamber, a substrate support, a plasma generator, and a bias power supply. The substrate support is provided in the chamber. The plasma generator is configured to generate plasma from gas in the chamber. The bias power supply is configured to apply a sequence of a plurality of voltage pulses as an electrical bias to the substrate support. The bias power supply is configured to adjust a maximum voltage level of each of the voltage pulses by adjusting a length of an ON period of each of the voltage pulses.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram for explaining a configuration example of a plasma processing system.

FIG. 2 is a diagram for explaining a configuration example of a capacitively coupled plasma processing apparatus.

FIG. 3 is a timing chart of an example of an electrical bias used in a plasma processing apparatus according to one exemplary embodiment.

FIG. 4 is a diagram illustrating a relationship between a voltage level and a length of an ON period in an exemplary voltage pulse.

FIG. 5 is an exemplary timing chart of an electrical bias used in a plasma processing apparatus according to one exemplary embodiment.

FIG. 6 is a diagram for explaining another configuration example of the capacitively coupled plasma processing apparatus.

FIG. 7 is a flowchart of a plasma processing method according to one exemplary embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, various exemplary embodiments will be described in detail with reference to the accompanying drawings. Like reference numerals will be given to like or corresponding parts throughout the drawings.

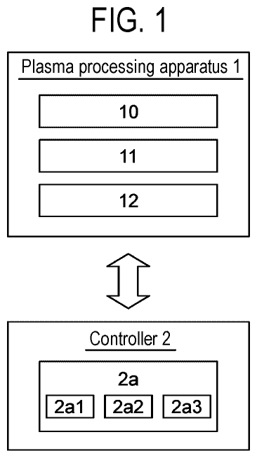

FIG. 1 is a diagram for explaining a configuration example of a plasma processing system. In one embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 also has at least one gas supply port for supplying at least one process gas to the plasma processing space and at least one gas exhaust port for exhausting gas from the plasma processing space. The gas supply port is connected to a gas supplier 20 described later, and the gas exhaust port is connected to an exhaust system 40 described later. The substrate support 11 is disposed in the plasma processing space and has a substrate support surface for supporting a substrate.

The plasma generator 12 is configured to generate plasma from the at least one process gas supplied to the plasma processing space. The plasma formed in the plasma processing space may be capacitively coupled plasma (CCP), inductively coupled plasma (ICP), electron cyclotron resonance (ECR) plasma, helicon wave plasma (HWP), or surface wave plasma (SWP). In addition, various types of plasma generators including an alternating current (AC) plasma generator and a direct current (DC) plasma generator may be used. In one embodiment, an AC signal (AC power) used in the AC plasma generator has a frequency in a range of 100 kHz to 10 GHz. Therefore, the AC signal includes a radio frequency (RF) signal and a microwave signal. In one embodiment, the RF signal has a frequency in a range of 100 kHz to 150 MHz.

The controller 2 processes a computer-executable instruction that causes the plasma processing apparatus 1 to execute various processes described in this disclosure. The controller 2 may be configured to control each element of the plasma processing apparatus 1 to execute various processes described herein. In one embodiment, a part or all of the controller 2 may be included in the plasma processing apparatus 1. The controller 2 may include a processor 2a1, a storage 2a2, and a communication interface 2a3. The controller 2 is realized, for example, by a computer 2a. The processor 2al may be configured to perform various control operations by reading a program from the storage 2a2 and executing the read program. This program may be stored in the storage 2a2, which is a non-transitory computer readable storage medium, in advance or may be acquired via a medium when necessary. The acquired program is stored in the storage 2a2 and is read from the storage 2a2 by the processor 2al and executed. The medium may be various storage media readable by the computer 2a or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

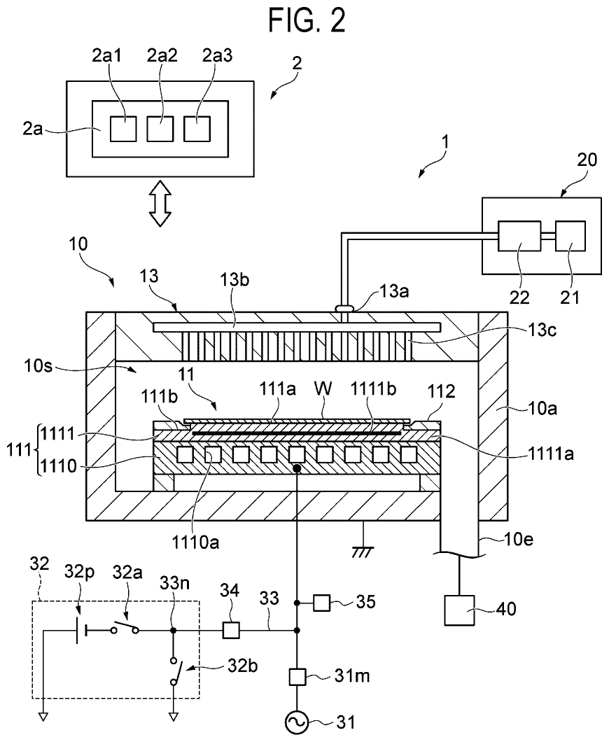

Hereinbelow, a configuration example of the CCP processing apparatus as an example of the plasma processing apparatus 1 will be described. FIG. 2 is a diagram for explaining a configuration example of the CCP processing apparatus.

The CCP processing apparatus 1 includes the plasma processing chamber 10, the gas supplier 20, and the exhaust system 40. The plasma processing apparatus 1 also includes the substrate support 11 and a gas introduction portion. The gas introduction portion is configured to introduce at least one process gas into the plasma processing chamber 10. The gas introduction portion includes a shower head 13. The substrate support 11 is disposed in the plasma processing chamber 10. The shower head 13 is disposed above the substrate support 11. In one embodiment, the shower head 13 constitutes at least a part of the ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The shower head 13 and the substrate support 11 are electrically insulated from the housing of the plasma processing chamber 10.

The substrate support 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 when viewed in a plan view. The substrate W is disposed on the central region 111a of the main body 111, and the ring assembly 112 is disposed on the annular region 111b of the main body 111 so as to surround the substrate W on the central region 111a of the main body 111. Therefore, the central region 111a is also called a substrate support surface for supporting the substrate W, and the annular region 111b is also called a ring support surface for supporting the ring assembly 112.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one embodiment, the ceramic member 1111a also has the annular region 111b. Another member surrounding the electrostatic chuck 1111, such as an annular electrostatic chuck or an annular insulating member, may have the annular region 111b. In this case, the ring assembly 112 may be disposed on the annular electrostatic chuck or the annular insulating member or may be disposed on both the electrostatic chuck 1111 and the annular insulating member. At least one electrode coupled to a radio frequency power supply 31 and/or a bias power supply 32 described later may be disposed in the ceramic member 1111a. In this case, the at least one electrode functions as the lower electrode. When an electrical bias described later is supplied to the at least one electrode, the at least one electrode is also called a bias electrode. The conductive member of the base 1110 and the at least electrode may function as a plurality of lower electrodes. Furthermore, the electrostatic electrode 1111b may function as the lower electrode. Therefore, the substrate support 11 includes at least one lower electrode.

The ring assembly 112 includes one or plural annular members. In one embodiment, the one or plural annular members include one or plural edge rings and at least one cover ring. The edge ring is formed of a conductive material or an insulating material, and the cover ring is formed of an insulating material.

The substrate support 11 may include a temperature adjustment module configured to adjust at least one of the electrostatic chuck 1111, the ring assembly 112, or the substrate to a target temperature. The temperature adjustment module may include a heater, a heat transfer medium, a flow passage 1110a, or a combination thereof. A heat transfer fluid such as brine or gas flows through the flow passage 1110a. In one embodiment, the flow passage 1110a is formed in the base 1110, and one or plural heaters are disposed in the ceramic member 1111a of the electrostatic chuck 1111. The substrate support 11 may include a heat transfer gas supplier configured to supply a heat transfer gas to a gap between a back surface of the substrate W and the central region 111a.

The shower head 13 is configured to introduce at least one process gas from the gas supplier 20 into the plasma processing space 10s. The shower head 13 has at least one gas supply port 13a, at least one gas diffusion chamber 13b, and a plurality of gas introduction ports 13c. The process gas supplied to the gas supply port 13a passes through the gas diffusion chamber 13b and is introduced into the plasma processing space 10s from the gas introduction ports 13c. The shower head 13 also includes at least one upper electrode. In addition to the shower head 13, the gas introduction portion may include one or plural side gas injectors (SGIs) installed in one or plural openings formed in the sidewall 10a.

The gas supplier 20 may include at least one gas source 21 and at least one flow rate controller 22. In one embodiment, the gas supplier 20 is configured to supply at least one process gas to the shower head 13 from each corresponding gas source 21 through each corresponding flow controller 22. Each flow controller 22 may include, for example, a mass flow controller or a pressure-controlled flow rate controller. In addition, the gas supplier 20 may include at least one flow rate modulation device that modulates or pulses the flow rate of the at least one process gas.

The exhaust system 40 may be connected to, for example, a gas exhaust port 10e provided in the bottom of the plasma processing chamber 10. The exhaust system 40 may include a pressure regulating valve and a vacuum pump. Pressure in the plasma processing space 10s is regulated by the pressure regulating valve. The vacuum pump may include a turbomolecular pump, a dry pump, or a combination thereof.

In one embodiment, the plasma processing apparatus 1 may further include a radio frequency power supply 31 as the plasma generator 12. The radio frequency power supply 31 is configured to generate source radio frequency power in order to generate plasma from gas in the chamber 10. The source radio frequency power has a frequency in a range of 10 MHz to 150 MHz. The radio frequency power supply 31 is electrically connected to the lower electrode or the upper electrode via a matcher 31m. The matcher 31m has a matching circuit for matching load impedance of the radio frequency power supply 31 to output impedance of the radio frequency power supply 31. The radio frequency power supply 31 may supply a continuous wave of the source radio frequency power. Alternatively, the radio frequency power supply 31 may periodically supply pulses of the source radio frequency power. The pulses of the source radio frequency power may be synchronized with pulses of an electrical bias described later.

In one embodiment, the plasma processing apparatus 1 further includes the bias power supply 32. The bias power supply 32 is configured to supply an electrical bias to the substrate support 11. The electrical bias may be supplied to the lower electrode. The electrical bias may be continuously supplied to the substrate support 11. Alternatively, pulses of the electrical bias may be supplied to the substrate support 11. The pulses of the electrical bias may be supplied at the same repetition period as the pulses of the source radio frequency power so as to be synchronized with the pulses of the source radio frequency power.

In one embodiment, a filter 34 may be connected between the bias power supply 32 and the substrate support 11. The filter 34 is an electrical filter that attenuates or blocks the source radio frequency power that can flow into the bias power supply 32.

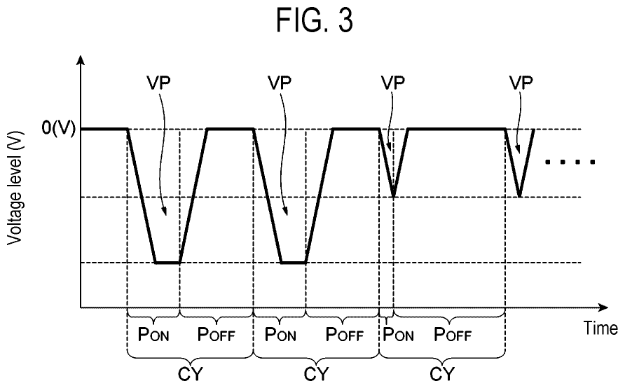

Reference is made to FIG. 3 in conjunction with FIG. 2. FIG. 3 is a timing chart of an exemplary electrical bias used in a plasma processing apparatus according to one exemplary embodiment. As illustrated in FIG. 3, an electrical bias and pulses thereof are a sequence of a plurality of voltage pulses VP. Each of the voltage pulses VP may be a pulse of a negative voltage or a negative DC voltage.

The electrical bias and pulses thereof, i.e., a sequence of the voltage pulses VP, has a waveform cycle CY. The waveform cycle CY includes an ON period P_{ON} and an OFF period P_{OFF}. The bias power supply 32 outputs a voltage during the ON period P_{ON} and stops outputting the voltage during the OFF period P_{OFF}. As a result, one voltage pulse VP is output during the waveform cycle CY. By repeating this waveform cycle CY, a sequence of the voltage pulses VP is output. A bias frequency, which is the reciprocal of a time length of the waveform cycle CY, is a frequency in a range of 100 kHz to 13.56 MHz, for example, 400 kHz.

As illustrated in FIG. 2, in one embodiment, the bias power supply 32 may include a DC power supply 32p, a first switch 32a, and a second switch 32b. The DC power supply 32p may be a variable DC power supply. A positive electrode of the DC power supply 32p is connected to a ground. A negative electrode of the DC power supply 32p is electrically connected to the substrate support 11 (e.g., the lower electrode) via the first switch 32a. The second switch 32b is connected between a node 33n on an electrical path 33 and the ground. The electrical path 33 electrically connects the DC power supply 32p and the substrate support 11 to each other. The node 33n is provided between the first switch 32a on the electrical path 33 and the substrate support 11. The first switch 32a is closed during the ON period P_{ON} and is open during the OFF period P_{OFF}. The second switch 32b is open during the ON period P_{ON} and is closed during the OFF period P_{OFF}.

The bias power supply 32 is configured to adjust a maximum voltage level of each of the voltage pulses VP by adjusting the length of the ON period P_{ON} of each of the voltage pulses VP, as illustrated in FIG. 3. When the voltage pulse VP is a pulse of a negative voltage or a negative DC voltage, the maximum voltage level is a voltage level whose absolute value is the maximum in the voltage pulse.

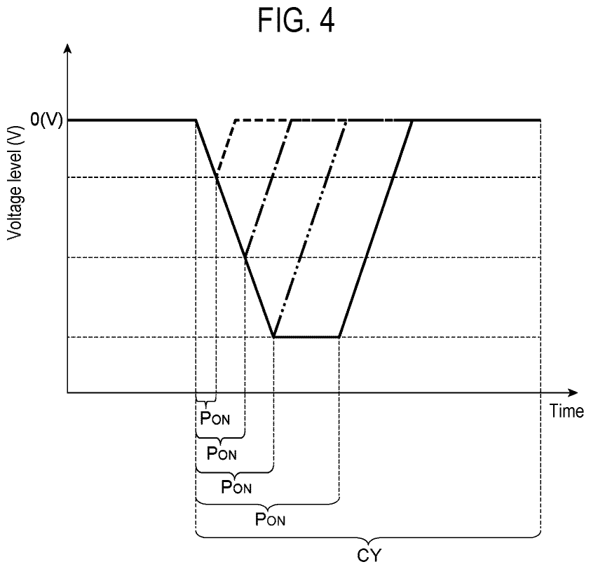

Here, reference is made to FIG. 4. FIG. 4 is a diagram illustrating a relationship between a voltage level and a length of an ON period in an exemplary voltage pulse. As illustrated in FIG. 4, the voltage level of the voltage pulse VP changes from the start of the ON period P_{ON} toward a maximum voltage level thereof. As illustrated in FIG. 4, the maximum voltage level of the voltage pulse VP depends on the length of the ON period P_{ON} in a range not reaching a level corresponding to a maximum absolute value of a voltage that the bias power supply 32 can output. Therefore, by adjusting the length of the ON period P_{ON}, it is possible to adjust the maximum voltage level of each of the voltage pulses VP.

In one embodiment, the controller 2 is configured to determine the length of the ON period P_{ON} from the maximum voltage level of each of the plural voltage pulses VP to be applied to the substrate support 11 using a relational equation. This relational equation is a function that relates the maximum voltage level of the voltage pulse VP to the length of the ON period P_{ON} and may be previously prepared. This relational equation may be specified when plasma processing is performed on the substrate W.

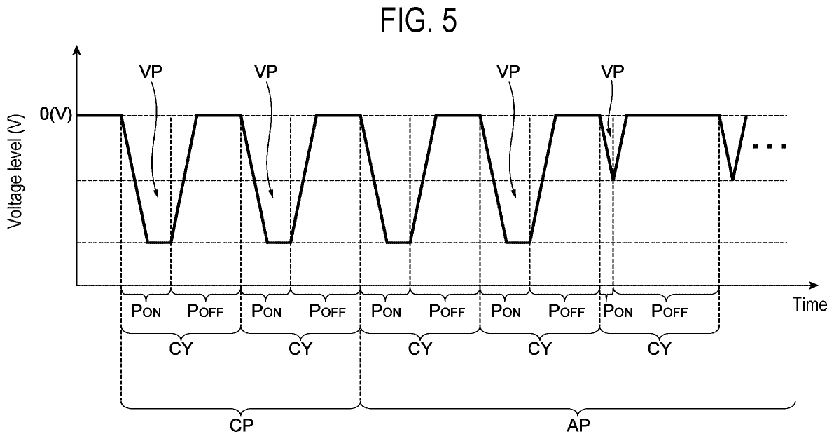

Here, reference is made to FIG. 5. FIG. 5 is an exemplary timing chart of an electrical bias used in a plasma processing apparatus according to one exemplary embodiment. In another embodiment, the controller 2 acquires a time change in the voltage level of at least one voltage pulse VP in a duration CP. The duration CP may be a duration during which the substrate W to be processed in a subsequent duration AP is placed on the substrate support 11 and plasma to used in the duration AP is generated. The time change in the voltage level of the at least one voltage pulse VP is a time change starting from application of the at least one voltage pulse VP. The at least one voltage pulse VP has a maximum voltage level that the bias power supply 32 can output.

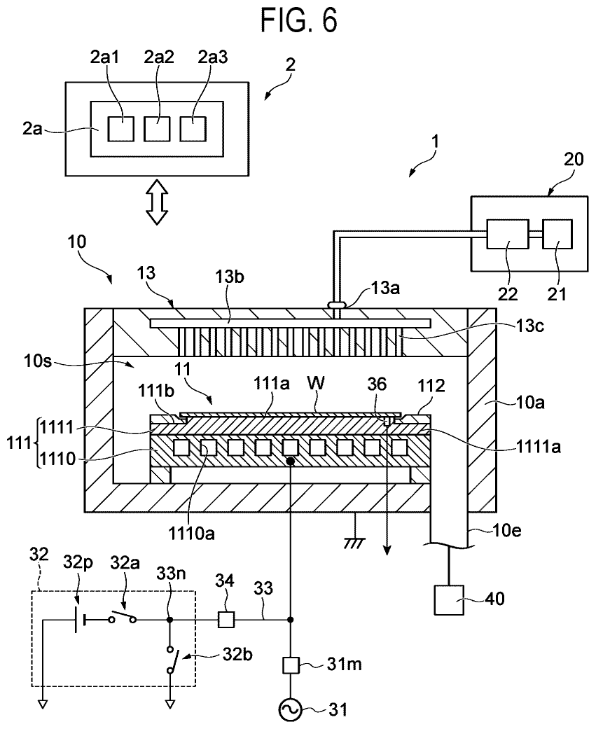

The time change in the voltage level of the at least one voltage pulse VP may be measured by a voltage sensor 35 (see FIG. 2). The voltage sensor 35 measures the voltage of the electrical path 33 or the lower electrode. Alternatively, the time change in the voltage level of the at least one voltage pulse VP may be measured by a voltage sensor 36 illustrated in FIG. 6. The voltage sensor 36 is disposed directly under the substrate W and is configured to measure the potential of the substrate W.

The controller 2 specifies a relational equation between the length of the ON period P_{ON} and the maximum voltage level of the voltage pulse VP from the time change of the voltage level of the at least one voltage pulse VP. The relational equation may be specified by a controller other than the controller 2.

The bias power supply 32 sets the length of the ON period P_{ON} of each of the voltage pulses VP to the length of the ON period P_{ON} determined by the controller 2. When the relational equation is specified in the duration CP, the bias power supply 32 sets the length of the ON period P_{ON} of each of the voltage pulses VP to the length of the ON period P_{ON} determined by the controller 2 in the duration AP after the duration CP. In one embodiment, the bias power supply 32 sets the length of a duration during which the first switch 32a is closed to the length of the ON period P_{ON} determined by the controller 2. As described above, the second switch 32b is opened in the duration during which the first switch 32a is closed. The length of the ON period P_{ON} of each of the voltage pulses VP may be determined by a controller other than the controller 2 and specified for the bias power supply 32.

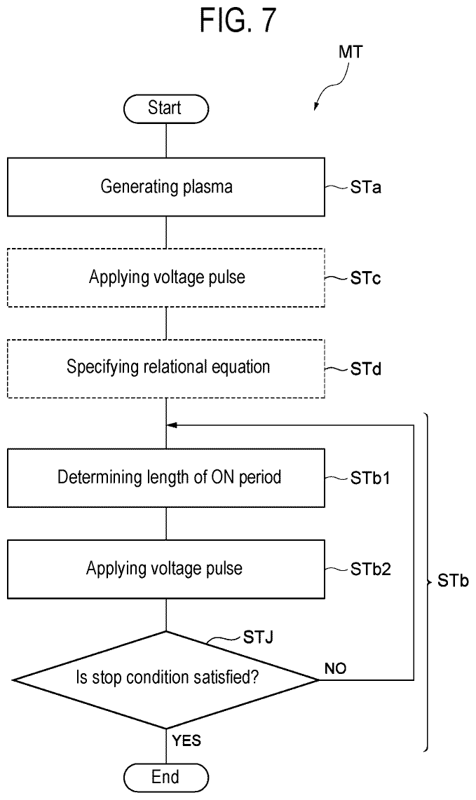

Hereinafter, reference will be made to FIG. 7. FIG. 7 is a flowchart of a plasma processing method according to one exemplary embodiment. In each step of the plasma processing method (referred to hereinafter as “method MT”) illustrated in FIG. 7, each portion of the plasma processing apparatus 1 can be controlled by the controller 2. The method MT includes step STa and step STb. In the method MT, prior to step STa, the substrate W is placed on the substrate support 11.

In step STa, plasma is generated in the chamber 10. In one embodiment, in order to generate the plasma, gas is supplied from the gas supplier 20 into the chamber 10. Pressure in the chamber 10 is adjusted to a specified pressure by the exhaust system 40. Radio frequency power is supplied from the radio frequency power supply 31. Step STa continues until step STb is completed.

In one embodiment, the method MT may further include step STc and step STd. Step STc is performed during the duration CP. In this case, step STb is performed during the duration AP after the duration CP. In step STc, as described above, at least one voltage pulse VP is applied to the substrate support 11 from the bias power supply 32. In step STd, the above-described relational equation is specified from a time change in a voltage level of the at least one voltage pulse VP. The relational equation can be determined by the controller 2 or another controller.

In step STb, a sequence of a plurality of voltage pulses VP is applied to the substrate support 11 from the bias power supply 32 in order to draw ions from the plasma to the substrate W on the substrate support 11. Step STb includes step STb1 and step STb2. In step STb1, the length of the ON period P_{ON} of the voltage pulse VP is determined from the maximum voltage level of the voltage pulse VP to be applied to the substrate support 11 based on the aforementioned relational equation. The length of the ON period P_{ON} can be determined by the controller 2 or another controller. In step STb2, the length of the ON period P_{ON} of the voltage pulse VP is set to the length of the ON period P_{ON} determined in step STb1. The voltage pulse VP, the length of the ON period P_{ON} of which is set, is applied to the substrate support 11.

In step STJ after step STb2, it is determined whether or not a stop condition is satisfied. The stop condition can be satisfied when a duration specified by recipe data ends. If it is determined in step STJ that the stop condition is not satisfied, step STb1 and step STb2 are repeated. By repeating step STb1 and step STb2, a sequence of the voltage pulses VP is applied to the substrate support 11. If it is determined in step STJ that the stop condition is satisfied, the method MT ends.

While various exemplary embodiments have been described, the present disclosure is not limited to the exemplary embodiments described above, and various additions, omissions, substitutions, and changes may be made. In addition, elements in different embodiments can be combined to form other embodiments.

According to one exemplary embodiment, it is possible to adjust a maximum voltage level of each of a plurality of voltage pulses applied as an electrical bias to a substrate support of a plasma processing apparatus.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A plasma processing apparatus, comprising:
a chamber;
a substrate support provided in the chamber;
a plasma generator configured to generate plasma from a gas in the chamber; and
a bias power supply configured to apply a sequence of a plurality of voltage pulses as an electrical bias to the substrate support,
wherein the bias power supply is configured to adjust a maximum voltage level of each of the voltage pulses by adjusting a length of an ON period of each of the voltage pulses.

2. The plasma processing apparatus of claim 1, further comprising a controller configured to determine the length of the ON period corresponding to the maximum voltage level of each of the voltage pulses to be applied to the substrate support using a previously prepared relational equation between the length of the ON period and the maximum voltage level,
wherein the bias power supply is configured to set the length of the ON period of each of the voltage pulses to the length of the ON period determined by the controller.

3. The plasma processing apparatus of claim 1, further comprising a controller,
wherein the controller is configured to
specify a relational equation between the length of the ON period and the maximum voltage level from a time change of a voltage level starting from application of at least one voltage pulse from the bias power supply to the substrate support, and
determine the length of the ON period corresponding to the maximum voltage level of each of the voltage pulses to be applied to the substrate support using the relational equation, and
wherein the bias power supply is configured to set the length of the ON period of each of the voltage pulses to the length of the ON period determined by the controller.

4. The plasma processing apparatus of claim 3, further comprising a voltage sensor configured to measure a voltage of an electrical path electrically connecting the bias power supply and the substrate support to each other,
wherein the time change of the voltage level is acquired by the voltage sensor.

5. The plasma processing apparatus of claim 3, further comprising a voltage sensor configured to measure a potential of a substrate placed on the substrate support,
wherein the time change of the voltage level is acquired by the voltage sensor.

6. The plasma processing apparatus of claim 1, wherein the bias power supply includes:
a direct current (DC) power supply;
a first switch connected between the DC power supply and the substrate support; and
a second switch connected between a node on an electrical path and a ground, the electrical path electrically connecting the DC power supply and the substrate support to each other, and
wherein the bias power supply adjusts the length of the ON period of each of the voltage pulses by adjusting a length of a duration during which the first switch is closed.

7. The plasma processing apparatus of claim 6, wherein the bias power supply is configured to close the second switch when the first switch is open.

8. A plasma processing method, comprising:
(a) generating plasma from gas in a chamber of a plasma processing apparatus; and
(b) applying a sequence of a plurality of voltage pulses as an electrical bias to a substrate support in the chamber from a bias power supply in order to draw ions from the plasm to the substrate support,
wherein, in (b), a maximum voltage level of each of the voltage pulses is adjusted by adjusting a length of an ON period of each of the voltage pulses.

9. The plasma processing method of claim 8, wherein, in (b), the length of the ON period of each of the voltage pulses corresponding to the maximum voltage level of each of the voltage pulses to be applied to the substrate support is determined using a previously prepared relational equation between the length of the ON period and the maximum voltage level.

10. The plasma processing method of claim 8, further comprising
specifying a relational equation between the length of the ON period and the maximum voltage level from a time change of a voltage level of at least one voltage pulse starting from application of the at least one voltage pulse from the bias power supply to the substrate support,
wherein, in (b), the length of the ON period of each of the voltage pulses corresponding to the maximum voltage level of each of the voltage pulses to be applied to the substrate support is determined using the relational equation.

11. The plasma processing apparatus of claim 2, wherein the bias power supply includes:
a direct current (DC) power supply;
a first switch connected between the DC power supply and the substrate support; and
a second switch connected between a node on an electrical path and a ground, the electrical path electrically connecting the DC power supply and the substrate support to each other, and
wherein the bias power supply adjusts the length of the ON period of each of the voltage pulses by adjusting a length of a duration during which the first switch is closed.
